(19) United States
(12) Patent Application Publication
(10) Pub. No.: US 2006/0225867 A1
(43) Pub. Date: Oct. 12, 2006

(54) Heat sink apparatus for electronic device

(75) Inventors: Hee-Sung Park, Suwon-si (KR); Kwang Kim, Suwon-si (KR); Jong-Tae Kang, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/346,196

(22) Filed: Feb. 3, 2006

(30) Foreign Application Priority Data
Apr. 11, 2005 (KR) 10-2005-0029954

(51) Int. Cl. H05K 7/20

(52) U.S. Cl. 165/80.4; 165/170; 361/699

(57) ABSTRACT

A heat sink apparatus is provided for an electronic device. The heat sink apparatus includes a body in which an inlet and an outlet are formed. A heat absorbing fluid flows through a plurality of channels. An inflow guide unit has a cross-section that narrows as it extends away from the inlet to guide substantially the same amount of the heat absorbing fluid into each of the channels. An outflow guide unit formed substantially identically to the inflow guide unit guides the heat absorbing fluid from the channels to the outlet.

### CROSS REFERENCE TO RELATED APPLICATION

This application claims the benefit under 35 U.S.C. § 119(a) of Korean Patent Application No. 10-2005-0029954, filed on Apr. 11, 2005 in the Korean Intellectual Property Office, the entire disclosure of which is hereby incorporated by reference.

### BACKGROUND OF THE INVENTION

1. Field of the Invention

The present invention relates to a heat sink apparatus for an electronic device. More particularly, the present invention relates to a heat sink apparatus for an electronic device that maintains a uniform flux of a heat absorbing fluid so that the temperature of a surface contacting the electronic device is substantially constant.

2. Description of the Related Art

Generally, electronic devices of sound devices or amplifiers of communication repeaters or computer electronic devices, such as central processing units (CPUs), graphic cards, power suppliers, and other similar electronic devices, generate heat while operating.

These electronic devices need to operate in an environment that satisfies certain conditions to be able to fully exhibit their functions because they are affected by their surrounding environment. Electronic devices are especially sensitive to heat among other environmental factors. Thus, if electronic devices are over heated, they can malfunction or even affect nearby devices.

That is why heat sinks are used in many electronic devices to absorb and dissipate heat generated while the electronic devices operate and cool the devices.

Examples of heat sinks are disclosed in U.S. Pat. Nos. 6,253,835 and 5,099,311.

FIG. 1 is a view of a conventional heat sink disclosed in U.S. Pat. No. 6,253,835, entitled “Isothermal Heat Sink with Converging, Diverging Channel.” Referring to FIG. 1, the heat sink absorbs heat produced by an IC package using a coolant fluid. The coolant fluid enters an inlet 31, propagates to an inlet plenum 30, and dissipates uniformly to multiple channels 22. Then, the coolant fluid is sent to an outlet plenum 34 and expelled through an outlet 35.

The surface of the heat sink is cooled by the coolant fluid flowing through the multiple channels 22 formed on the surface of the heat sink contacting the IC package. To uniformly dissipate the coolant fluid into the channels 22, plenums are formed on the bottom surface of the channels 22 so that the coolant fluid propagating from the inlet 31 and to the outlet 35 has a uniform pressure in each of the channels 22.

However, the inlet plenum 30 and the outlet plenum 34 are formed in different layers in U.S. Pat. No. 6,253,835. Therefore, a separate device (that is, a plenum) is added to uniformly distribute the coolant fluid to other parts of the heat sink besides the surface for cooling, thereby increasing the height of the heat sink. Consequently, the heat sink cannot be used in a compact system or a slim system.

A “Microchannel Heat Sink Assembly” disclosed in U.S. Pat. No. 5,099,311 has a plurality of microchannels to cool the surface of an IC chip. Grooves are formed on inlets and outputs to be used as plenums so that a uniform amount of coolant fluid can be supplied to each of the microchannels. Also, a manifold layer for the inflow and outflow of the coolant is formed at the bottom surface of a microchannel layer to uniformly distribute the coolant to each of the channels.

However, the microchannels and the manifold layer are directly connected to each other, which increases the thickness of the heat sink. Therefore, the microchannel heat sink assembly cannot not be used in slim electronic devices.

Accordingly, a need exists for an improved heat sink that flows substantially uniform amounts of fluid through a plurality of channels without substantially increasing the volume of the heat sink.

### SUMMARY OF THE INVENTION

Embodiments of the present invention provide a heat sink apparatus for an electronic device that controls the amount of heat absorbing fluid flowing into and out of a plurality of channels without additional structure so that a uniform amount of the heat absorbing fluid flows in the plurality of channels.

According to an aspect of embodiments of the present invention, a heat sink apparatus for an electronic device includes a body having an inlet, an outlet, and a plurality of channels through which a heat absorbing fluid flows. An inflow guide unit has a cross-section that narrows as it extends away from the inlet to guide the same amount of the heat absorbing fluid into each of the channels. An outflow guide unit is formed substantially identically to the inflow guide unit to guide the heat absorbing fluid from the channels to the outlet.

Other objects, advantages, and salient features of the invention will become apparent from the detailed description, which, taken in conjunction with the annexed drawings, discloses preferred exemplary embodiments of the invention.

### BRIEF DESCRIPTION OF THE DRAWINGS

The above and other features and advantages of the present invention will become more apparent by describing in detail exemplary embodiments thereof with reference to the attached drawings, in which:

FIG. 1 is an elevational view in cross section of a conventional heat sink disclosed in U.S. Pat. No. 6,253,835;

FIG. 2 is an elevational view in cross section of a heat sink apparatus for an electronic device according to a first exemplary embodiment of the present invention;

FIG. 3 is an elevational view in cross-section of the heat sink apparatus of FIG. 2 taken along line III-III′ of FIG. 2;

FIG. 4 is an elevational view in cross-section of the heat sink apparatus of FIG. 2 taken along line IV-IV′ in FIG. 2;

FIG. 5 is a drawing explaining a mathematical model of the heat sink apparatus illustrated in FIG. 2;

FIG. 6 is an elevational view in cross section of a heat sink apparatus according to a second exemplary embodiment of the present invention;

FIG. 7 is an elevational view in cross section of a heat sink apparatus according to a third exemplary embodiment of the present invention;

FIG. 8 is an elevational view in cross section of a heat sink apparatus according to a fourth exemplary embodiment of the present invention;

FIG. 9 is a drawing explaining a mathematical model of the heat sink apparatus of claim 8;

FIG. 10 is an elevational view in cross section of a heat sink apparatus according to a fifth exemplary embodiment of the present invention; and

FIG. 11 is an elevational view in cross section of a heat sink apparatus according to a sixth exemplary embodiment of the present invention.

Throughout the drawings, like reference numerals will be understood to refer to like parts, components and structures.

### DETAILED DESCRIPTION OF EXEMPLARY EMBODIMENTS

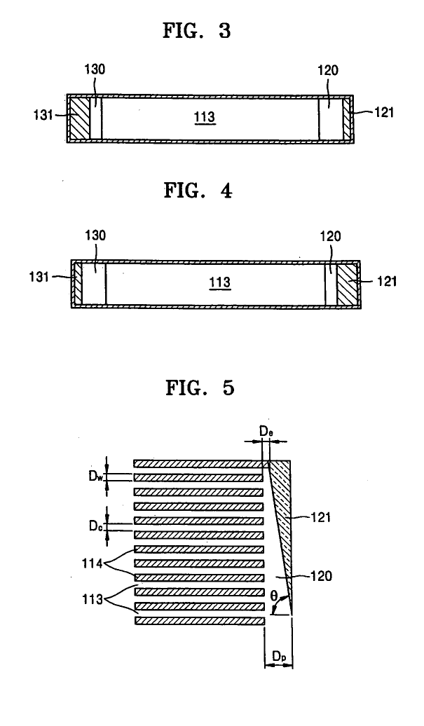

FIG. 2 is an elevational view in cross section of a heat sink apparatus 100 for an electronic device (not shown) according to a first exemplary embodiment of the present invention. FIG. 3 is an elevational view in cross-section of the heat sink apparatus 100 taken along the line III-III′ in FIG. 2. FIG. 4 is an elevational view in cross-section of the heat sink apparatus 100 taken along the line IV-IV′ in FIG. 2.

Referring to FIG. 2, the heat sink apparatus 100 includes a body 110, a plurality of channels 113, an inflow guide unit 120, and an outflow guide unit 130.

An absorbing fluid enters the body 110 and absorbs heat produced by the electronic device. The body 110 is sealed except for an inlet 111 and an outlet 112 through which the heat absorbing fluid flows.

The plurality of channels 113 are partitioned at predetermined intervals by a plurality of channel walls 114 inside the body 110 so that the heat absorbing fluid may flow through each of the channels 113. The channels 113 are horizontally disposed between the inflow guide unit 120 and the outflow guide unit 120, and may have various cross-sections, such as a rectangular or a circular cross-section.

The inflow guide unit 120 formed at one side of the plurality of channels 113, that is, proximal where the inlet 111 is formed, guides the heat absorbing fluid that enters through the inlet 111 into each of the channels 113. The inflow guide unit 120 includes an inflow guide plate 121.

The inflow guide plate 121 has a surface inclined towards the channels 113 as it gets further away from the inlet 111, that is, as it reaches the furthest channel 113 from the inlet 111. Thus, the cross-section of the inflow guide unit 120 narrows as the inflow gate plate 121 extends away from the inlet 111, as illustrated in FIGS. 3 and 4. Therefore, uniform amounts of the heat absorbing fluid entering through the inlet 111 propagate into each of the channels 113.

The outflow guide unit 130 formed at the other side of the channels 113, that is, proximal where the outlet 113 is formed, guides the heat absorbing fluid that passes through the channels 113 to propagate to the outlet 112. The outflow guide unit 130 includes an outlet guide plate 131.

The outflow guide plate 131, formed in substantially the same shape as the inlet guide plate 131, is intercomplementary with the inlet guide plate 131. The largest cross-section of the inflow guide unit 120 is at the end proximal the inlet 111 while the narrowest cross-section of the outflow guide unit 130 is at the end opposite to the outlet 112. Thus, the sum of the areas of the inflow guide unit 120 and the outflow guide unit 130 are the same for all of the channels 113. As a result, uniform amounts of the heat absorbing fluid flow through the channels 113.

The outflow guide plate 131 makes the same amount of the heat absorbing fluid flow through the channels 113 along with the inflow guide plate 121. Thus, the heat absorbing fluid flowing through each of the channels 113 absorbs the same amount of heat from the electronic device, thereby enabling the electronic device to operate at a proper temperature.

FIG. 5 is a drawing explaining a mathematical model of the heat sink apparatus 100 illustrated in FIG. 2.

Referring to FIG. 5, Dₚ indicates the largest diameter of the inflow guide unit 120, and Dₑ indicates the narrowest width of the inflow guide unit 120. If n indicates the number of channels 113, then

$$De = \frac{Dp}{n} \qquad ( 1 )$$

Also, D_{w} indicates the thickness of the channels 113, and D_{c} indicates the diameter of the channels 113. If the angle of the inflow guide unit 120 at which the inflow guide plate 121 is inclined is θ, then

$$θ = {tan}^{- 1} [ \frac{Dc + Dw}{De} ] \qquad ( 2 )$$

For example, if Dₚ=3 mm, Dₑ=0.1 mm, n=30, and D_{w}=0.1 mm, θ is 63.5° when calculating using Equations 1 and 2.

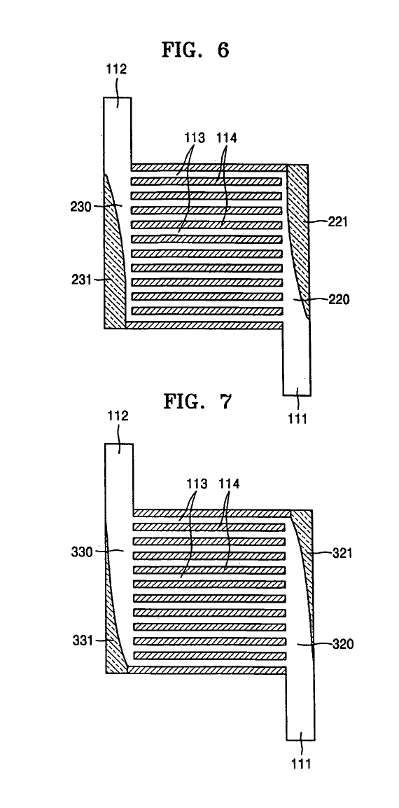

FIG. 6 is a sectional view of a heat sink apparatus according to a second exemplary embodiment of the present invention.

Referring to FIG. 6, reference numerals that are the same in FIG. 2 indicate like elements. In the heat sink apparatus according to the second exemplary embodiment, a surface of an inflow guide plate 221 facing a plurality of channels 113 is convexed from an inlet 111 towards the channels 113 as the inflow guide plate 221 extends away further away from an inlet 111. Thus, the cross-section of the inflow guide unit 220 narrows as it extends away from the inlet 111. An outflow guide plate 231 has a substantially identical shape with the inflow guide plate 221. Because the inflow and outflow guide units 220 and 221 respectively act like the inflow guide plate 121 and the outflow guide plate 131 according to the first exemplary embodiment of the present invention, the descriptions thereof are omitted.

FIG. 7 is a sectional view of a heat sink apparatus according to a third exemplary embodiment of the present invention.

Reference numerals in FIG. 7 that are the same as those in FIG. 2 indicate like elements. In the heat sink apparatus according to the third exemplary embodiment, a surface of an inflow guide plate 321 facing a plurality of channels 113 is concaved from an inlet 111 towards the channels 113 as the inflow guide plate 321 extends away from the inlet 111. Thus, the cross-section of an inflow guide unit 320 narrows as it extends away from the inlet 111. An outflow guide plate 331 has a substantially identical shape with the inflow guide plate 321. Because the inflow and outflow guide units 320 and 321 respectively act like the inflow guide plate 121 and the outflow guide plate 131 according to the first exemplary embodiment of the present invention, the descriptions thereof are omitted.

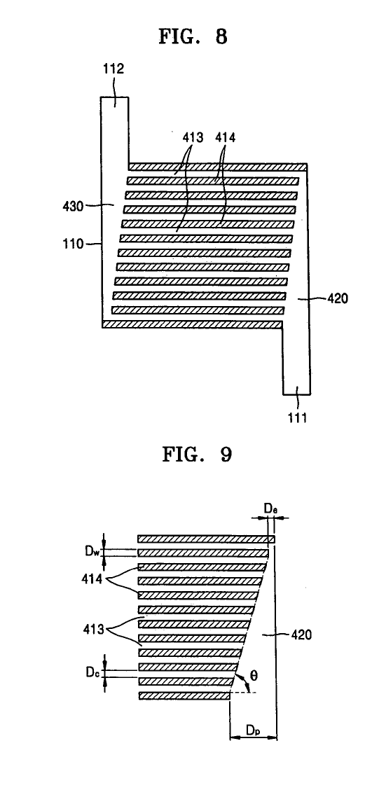

FIG. 8 is an elevational view in cross section of a heat sink apparatus according to a fourth exemplary embodiment of the present invention. FIG. 9 is a drawing explaining a mathematical model of the heat sink apparatus of claim 8.

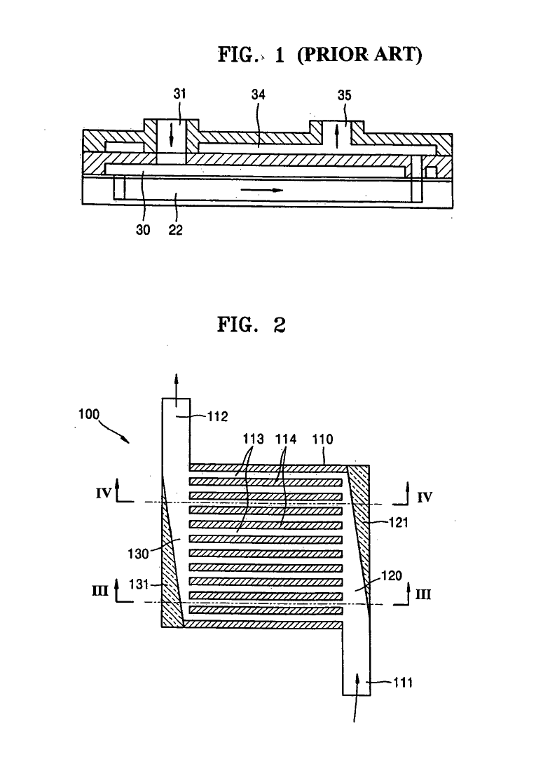

Referring to FIGS. 8 and 9, the heat sink apparatus according to the fourth exemplary embodiment is substantially similar to the heat sink apparatus 100 according to the first exemplary embodiment except that it does not have the inflow guide plate 121 and the outflow guide plate 131 in the first exemplary embodiment, and the shape of a plurality of channels 413 is different from that of the plurality of channels 113 of the first exemplary embodiment. The reference numbers in FIGS. 8 and 9 that are the same as in FIG. 1 denote like elements.

The heat sink apparatus includes a body 110, the plurality of channels 413, an inflow guide unit 420, an outflow guide unit 430, an inlet 111 and an outlet 112.

A heat absorbing fluid enters the body 110 through the inlet 111, absorbs heat produced by an electronic device (not shown), and exits from the body 110 via the outlet 112.

The plurality of channels 413 are partitioned at predetermined intervals by a plurality of channel walls 414 inside the body 110 so that the heat absorbing fluid may flow through each of the channels 413. The channels 413 are disposed between the inflow guide unit 420 and the outflow guide unit 430 and may have various cross-sections, such as a rectangular or circular cross section.

Distances between first ends of the channels 413 and the inflow guide unit 420 get successively smaller toward an upper end of the inflow guide 420. That is, the cross-sections of the inflow guide unit 420 narrows as it extends away from the inlet 111.

The first ends of the plurality of channels 413 form an inclined line. A mathematical model of the heat sink apparatus of FIG. 8 may be derived using Equations 1 and 2 and FIG. 8.

Additionally, distances between second ends of the channels 413 and the outflow guide unit 430 get successively smaller toward a lower end of the outflow guide 430. That is, the cross-sections of the outflow guide unit 430 narrows as it extends away from the outlet 112.

The second ends of the channels 413 form an inclined line substantially parallel to the inclined line formed by the first ends of the channels 413.

Therefore, uniform amounts of the heat absorbing fluid entering through the inlet 111 may flow through each of the plurality of channels 413 since the areas of the inflow guide unit 420 and the outflow guide unit 430 get narrower and wider, respectively.

Consequently, there is no need to use the inflow guide plates 121, 221, or 321 or the outflow guide plate 131, 231, or 331 of the first through third exemplary embodiments of the present invention.

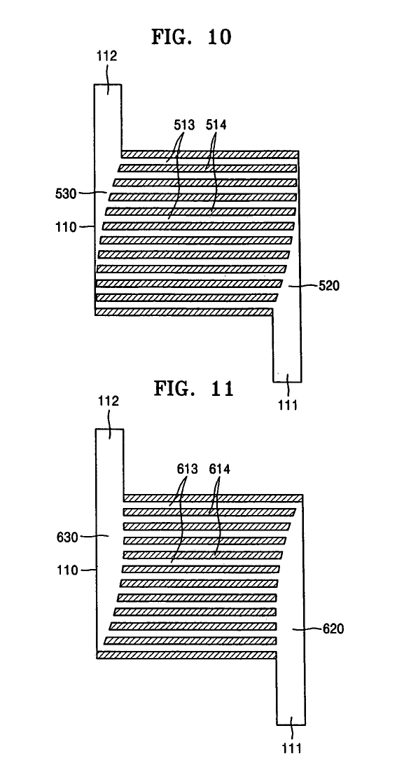

FIG. 10 is an elevational view in cross section of a heat sink apparatus according to a fifth exemplary embodiment of the present invention.

Referring to FIG. 10, reference numbers of the heat sink apparatus according to the fifth exemplary embodiment that are the same as in the heat sink apparatus illustrated in FIG. 9 denote like elements. Distances between first ends of a plurality of channels 513 and an inflow guide unit 520 get successively smaller toward an upper end of the inflow guide 520. That is, the cross-sections of the inflow guide unit 520 narrows as it extends away from the inlet 111. Additionally, distances between second ends of the channels 513 and the outflow guide unit 530 get successively smaller toward a lower end of the outflow guide 530.

The first and second ends of the plurality of channels 513 form convex lines, respectively protruding towards the inflow guide unit 520 and the outflow guide unit 530. The shapes formed by the first and second ends of the plurality of channels 513 have the same function as those formed by the first and second ends of the plurality of channels 413 illustrated in FIG. 9, and thus their descriptions are omitted.

FIG. 11 is a sectional view of a heat sink apparatus according to a sixth exemplary embodiment of the present invention.

Referring to FIG. 11, reference numbers of the heat sink apparatus according to the sixth exemplary embodiment that are the same as in the heat sink apparatus illustrated in FIG. 9 denote like elements. Distances between first ends of a plurality of channels 613 and an inflow guide unit 620 get successively smaller toward an upper end of the inflow guide 620. That is, the cross-sections of the inflow guide unit 620 narrows as it gets further away from the inlet 111. Additionally, distances between second ends of the channels 613 and the outflow guide unit 630 get successively smaller toward a lower end of the outflow guide 630.

The first and second ends of the channels 613 form concave lines, respectively recessing towards the inflow guide unit 620 and the outflow guide unit 630. The shapes formed by the first and second ends of the channels 613 have the same functions as those formed by the first and second ends of the channels 413 illustrated in FIG. 9, and thus their descriptions are omitted.

The heat sink according to the first through sixth exemplary embodiments is made of a material with high heat conductivity, preferably pure copper, brass, duralumin, or aluminum. The heat absorbing fluid, which absorbs and transports heat, may be a cooling agent, such as for example, air, fluid nitrogen, water, or liquids, such as fluorocarbon.

As described above, a heat sink apparatus according to exemplary embodiments of the present invention has a plurality of channels through which substantially constant amounts of a heat absorbing fluid flow to uniformly absorb heat through the entire contacting surface with an electronic device. Thus, since the volume of the heat sink apparatus is not increased, the heat sink apparatus may be conveniently used in a compact electronic device.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A heat sink apparatus for an electronic device, comprising:
a body in which an inlet, an outlet, and a plurality of channels are formed through which a heat absorbing fluid flows;
an inflow guide unit having a cross-section that narrows as it extends away from the inlet to guide substantially the same amount of the heat absorbing fluid into each of the channels; and
an outflow guide unit formed substantially identically to the inflow guide unit to guide the heat absorbing fluid from the channels to the outlet.

2. The heat sink apparatus of claim 1, wherein the inflow guide unit includes
an inflow guide plate, a surface of which faces the plurality of channels and is inclined towards the channels as the inflow guide plate extends further away from the inlet so that a cross-section of the inflow guide plate widens as the inflow guide plate extends away from the inlet.

3. The heat sink apparatus of claim 1, wherein the inflow guide unit includes
an inflow guide plate, a surface of which faces the plurality of channels and is curved towards the channels as the inflow guide plate extends further away from the inlet so that a cross-section of the inflow guide plate widens as the inflow guide plate extends further away from the inlet.

4. The heat sink apparatus of claim 3, wherein
the surface of the inflow guide plate facing the plurality of channels is convex.

5. The heat sink apparatus of claim 3, wherein
the surface of the inflow guide plate facing the plurality of channels is concave.

6. The heat sink apparatus of claim 1, wherein
the plurality of channels have first and second ends, and the distances between the first ends and the inflow guide unit become smaller further away from the inlet.

7. The heat sink apparatus of claim 6, wherein
the distances between the second ends and the outflow guide unit become smaller further away from the outlet.

8. The heat sink apparatus of claim 7, wherein
the first and second ends form substantially straight and parallel inclined lines extending away from the inlet and the outlet, respectively.

9. The heat sink apparatus of claim 7, wherein
the first and second ends form a concave curve extending away from the inlet and the outlet, respectively.

10. The heat sink apparatus of claim 7, wherein
the first and second ends form convex curves extending away from the inlet and the outlet, respectively

11. A heat sink apparatus for an electronic device, comprising:
a body in which an inlet, an outlet, and a plurality of channels are formed through which a heat absorbing fluid flows;
an inflow guide unit for guiding the heat absorbing fluid to flow into the plurality of channels; and
an outflow guide unit for guiding the heat absorbing fluid from the plurality of channels to the outlet;
wherein the plurality of channels are disposed to respectively extend further towards the inlet guide unit and the outlet guide unit as the plurality of channels are disposed further away from the inlet and the outlet, respectively, such that cross-sections of the inlet guide unit and the outlet guide unit narrow as inlet and outlet guide units respectively extend away from the inlet and the outlet, thereby allowing substantially the same amount of the heat absorbing fluid to flow through each of the plurality of channels.

12. The heat sink apparatus of claim 11, wherein
ends of the plurality of channels respectively corresponding to the inlet guide unit and the outlet guide unit respectively form inclined lines substantially parallel to each other.

13. The heat sink apparatus of claim 11, wherein
ends of the channels respectively corresponding to the inlet guide unit and the outlet guide unit respectively form convex curves.

14. The heat sink apparatus of claim 11, wherein
ends of the channels respectively corresponding to the inlet guide unit and the outlet guide unit respectively form concave lines.
